(19) United States
(12) Patent Application Publication
(10) Pub. No.: US 2026/0098890 A1
(43) Pub. Date: Apr. 9, 2026

(54) Progressive Power Grid Planning Evaluation Method and System Based on Combination Assessment Theory

(71) Applicant: Guizhou Power Grid Co., Ltd., Guiyang (CN)

(72) Inventors: Xin HE, Guiyang (CN); Yu ZHANG, Guiyang (CN); Zhaofeng ZHANG, Guiyang (CN); Xueyong TANG, Guiyang (CN); Julong CHEN, Guiyang (CN); Ning LUO, Guiyang (CN); Bin WANG, Guiyang (CN); Yang LI, Guiyang (CN); Qingsheng LI, Guiyang (CN); Chen LUO, Guiyang (CN); Yan ZHANG, Guiyang (CN); Rong WANG, Guiyang (CN); Hongyu RAO, Guiyang (CN); Ludong CHEN, Guiyang (CN)

(21) Appl. No.: 19/009,099

(22) Filed: Jan. 3, 2025

Related U.S. Application Data
(63) Continuation of application No. PCT/CN2024/135897, filed on Nov. 29, 2024.

(30) Foreign Application Priority Data
Oct. 8, 2024 (CN) 2024113907364

(51) Int. Cl. G01R 31/08

(52) U.S. Cl. CPC G01R 31/088; G01R 31/086

(57) ABSTRACT

The present invention discloses a progressive power grid planning evaluation method and system based on a combination assessment theory, and relates to the technical field of power grid assessment and optimization. The method includes: correcting a weight of an obtained index by using a combination weighting method; obtaining an assessed value based on a similarity theory assessment method; standardizing an index by dimensionless processing; and performing evaluation based on nonparametric regression. The present invention ensures objectivity and fairness of an assessment result and the efficiency and the accuracy of assessment are improved. The present invention may be adaptively adjusted, making the assessment result closer to reality.

### CROSS-REFERENCE TO RELATED APPLICATIONS

The present application claims priority to Chinese Patent Application No. 2024113907364, filed on Oct. 8, 2024, the entire disclosure of which is incorporated herein by reference.

### TECHNICAL FIELD

The present invention relates to the technical field of power grid assessment and optimization, and in particular to a progressive power grid planning evaluation method based on a combination assessment theory and a system.

### BACKGROUND

It is an important way to achieve the goal of “carbon peak and carbon neutrality” to construct a clean, efficient, safe, and low-carbon energy system guided by electrification, cleanliness, digitization, and standardization. With the rapid development of the power industry, the demand for building distribution networks is increasing. Meanwhile, building the distribution networks presents the characteristics of a wide coverage, a large scale and many related factors. These factors make planning, transformation, and building of the distribution networks become a huge and complex system engineering. The distribution network is located at an end of a power system, and is directly connected to a client, reflecting an operating capacity of the entire power system. With the gradual increase of the scale of the distribution network, planning and design problems of the distribution network have gradually become an increasingly concerned issue in the power industry. In order to achieve economic or security optimization of building the distribution network, it is necessary to comprehensively and accurately assess an operation level of the distribution network. Therefore, it is necessary to establish a comprehensive and accurate assessment index system to objectively measure effectiveness and achievements of planning. Weight distribution of assessment indexes is a key problem in the evaluation process. Different indexes have different importance in distribution network planning; while a traditional weighting method is often based on subjective judgments or expert opinions, and is easily affected by subjective bias and uncertainty, resulting in a deviation in an assessment result. Because of this, a research on an objective weighting method and a subjective and objective mixed interval affine weighting method can consider a relationship between the indexes and weight distribution under the uncertainty, which can improve accuracy and reliability of the assessment result.

### SUMMARY

In view of the existing problems mentioned above, the present invention is provided.

Therefore, the technical problem solved by the present invention is how to assess performance and a state of a power grid more accurately and efficiently.

To solve the above technical problem, the present invention provides the following technical solution: a progressive power grid planning evaluation method based on a combination assessment theory includes the following steps:
acquiring power grid system data, and correcting a weight of the collected power grid system data based on a combination weighting method; obtaining an assessed value based on a similarity theory assessment method; standardizing an index by dimensionless processing; and performing evaluation based on nonparametric regression. As a preferred solution of the progressive power grid planning evaluation method based on the combination assessment theory of the present invention, the power grid system data includes power grid operation state data, power grid equipment operation data, power grid load data, power grid fault data, and power grid environment data.

The combination weighting method includes a subjective weighting method and an objective weighting method, and the weighting method is selected according to the performance analysis of a power grid system.

A data index of the power grid system is assessed according to the subjective weighting method to generate a judgment matrix, normalization checking is preformed on the judgment matrix, and a system weight of the matrix is obtained by iterative calculation;

The data index of the power grid system is weighted by the objective weighting method to generate an original data matrix, and a comprehensive weight of the power grid system is obtained by dimensionless processing and normalization processing on a weight value.

The generating a judgment matrix includes: comparing evaluation factors, and filling a comparison result into the judgment matrix.
the normalization checking represents that

$$CI = \frac{{λ}_{m ax} - u}{n - 1}$$

$$CR = \frac{CI}{RI}$$

if CR is smaller than 0.1, normalization checking passes,
where CI represents a consistency index, π_{mad} represents a maximum eigenvalue of the judgment matrix, CR represents a consistency ratio, RI represents a random consistency index, and n represents a number of the evaluation factors.

As a preferred solution of the progressive power grid planning evaluation method based on the combination assessment theory of the present invention, the obtaining a comprehensive weight of the power grid system includes: calculating a weight of each data index according to the objective weighting method, and performing a check according to the Kendalls's concordance coefficient test method.

If d(W⁽¹⁾, W⁽²⁾) is larger than a test threshold, it represents that a test passes; and if the test passes, the comprehensive weight of the power grid system is calculated by using

$$W = {\sum }_{k = 1}^{q} {λ}_{k} {W}^{( k )}$$

the Kendall's concordance coefficient test method is expressed as:

$$d ( {W}^{( 1 )} , {W}^{( 2 )} ) = {[ \frac{1}{2} {\sum }_{j = 1}^{n} {( {w}_{j}^{( 1 )} - {w}_{j}^{2} )}^{2} ]}^{\frac{1}{2}}$$

where d(W⁽¹⁾, W⁽²⁾) represents an Euclidean distance between weight vectors W⁽¹⁾ and W⁽²⁾;

$${( {W}_{j}^{( 1 )} - {W}_{j}^{( 2 )} )}^{2}$$

represents a square of a difference between the weight values of the two weight vectors at the j^{th} position;

$${\sum }_{j = 1}^{n}$$

represents calculation on all weight differences; W represents the comprehensive weight of the power grid system; λₖ represents a weight of the k^{th} evaluation standard; and q represents a total number of evaluation standards.

As a preferred solution of the progressive power grid planning evaluation method based on the combination assessment theory of the present invention, the similarity theory assessment method includes: constructing a new model for power grid system level evaluation by a Shepard similarity interpolation method based accelerated genetic algorithm and an ideal interval method based on a genetic algorithm.

The constructing a new model for power grid system level evaluation includes: randomly generating power grid data evaluation level sample series x(i, j) and y(i) according to a system evaluation standard table, where i=1−n, and j=1−m; and
performing optimization estimation according to a sample parameter b, taking a sample i from the sample series, and obtaining an interpolation, denoted as y_{c}(i), corresponding to an evaluation level y(i) by Shepard interpolation with other n−1 samples. the accelerated genetic algorithm is expressed as:

$$\begin{matrix}min f ( b ) = {\sum }_{i = 1}^{n} \vert {y}_{c} ( i ) - y ( i ) \vert \\ s . t . 1 \leq b \leq 5\end{matrix}$$

where

$${\sum }_{i = 1}^{n}$$

represents a summation symbol, y_{c}(i) represents the i^{th} observed value, y(i) represents the i^{th} actual value, and s.t. represents a constraint condition.

The ideal interval method based on the genetic algorithm includes: generating the evaluation standard sample series, performing dimensionless processing, calculating a distance between each standard sample and a standard level ideal interval, and calculating a relative membership degree value and an equivalent comprehensive evaluation of each standard sample to the standard level ideal interval.

As a preferred solution of the progressive power grid planning evaluation method based on the combination assessment theory of the present invention, the dimensionless processing is expressed as:

$$x ( k , j ) = x * ( k , j ) / {x}_{max} ( j ) ( k = 1 \sim {n}_{k} , j = 1 \sim {n}_{j} )$$

$$a ( i , j ) = a * ( i , j ) / {x}_{max} ( j ) ( i = 1 \sim {n}_{i} , j = 1 \sim {n}_{j} )$$

$$b ( i , j ) = b * ( i , j ) / {x}_{max} ( j ) ( i = 1 \sim {n}_{i} , j = 1 \sim {n}_{j} )$$

where x(k, j), a(i, j), b(i, j) represent two-dimensional, variables, x*(k, j), a*(i, j), and b*(i, j) represent original values of x(k, j), a(i, j), and b(i, j) respectively, and xₘₐₓ(j) represents a maximum value of the j^{th} evaluation index that may be taken from the evaluation standard sample series, expressed as:

$${x}_{max} ( j ) = {max}_{i} \{ b * ( i , j ) \}$$

the distance between each standard sample and the standard level ideal interval is expressed as:

$$S ( k , i ) = {\sum }_{j = 1}^{{n}_{j}} w ( j ) d ( k , i , j )$$

$$d \{ \begin{matrix}a ( i , j ) - x ( k , j ) , & x ( k , j ) < a ( i , j ) \\ 0 , & x ( k , j ) ∈ [ a ( i , j ) , b ( i , j ) ] \\ x ( k , j ) - b ( i , j ) , & x ( k , j ) > b ( i , k )\end{matrix}$$

where D(k, i) represents a total distance between the k^{th} observed value and the i^{th} reference value, w(j) represents a weight of the j^{th} index, d(k, i, j) represents a distance between the k^{th} observed value and the i^{th} reference value on the j^{th} feature, a(i, j) and b(i, j) represent a lower bound and an upper bound of the i^{th} reference value on the j^{th} feature, and x(k, j) represents a value of the k^{th} observed value on the j^{th} feature.

As a preferred solution of the progressive power grid planning evaluation method based on the combination assessment theory of the present invention, the performing evaluation based on nonparametric regression includes: obtaining a one-dimensional projection value z(i) of the assessed value, expressed as:

$$z ( i ) = {\sum }_{j = 1}^{p} a ( j ) x ( i , j )$$

obtaining a projection index function by means of the one-dimensional projection value, expressed as:

$$Q ( a ) = {S}_{z} \vert {R}_{xy} \vert$$

where [symbol] represents an absolute value, and S_{z} represents a standard deviation of a projection value z(i);
estimating an optimal projection direction by solving a maximization problem of the projection index function

$$\begin{matrix}max Q ( a ) = {S}_{z} \vert {R}_{xy} \vert \\ s . t . {\sum }_{j = 1}^{p} {a}^{2} ( j ) = 1 ;\end{matrix}$$

and
performing optimization by using the accelerated genetic algorithm.

As a preferred solution of the progressive power grid planning evaluation method based on the combination assessment theory of the present invention, the performing evaluation based on nonparametric regression further includes: establishing a corresponding a Nadaraya-Watson nonparametric model, expressed as:

$${y}_{c} ( k ) = \frac{{\sum }_{i = 1}^{n} K ( ( {z}^{*} ( i ) - z ( k ) ) / h ) y ( i )}{{\sum }_{i = 1}^{n} K ( ( {z}^{*} ( i ) - z ( k ) ) / h )}$$

performing optimization estimation by using a standard evaluation object series {z*(i)|i=1˜n} and the accelerated genetic algorithm to solve the following optimization problems, expressed as:

$$\begin{matrix}min f ( h ) = {\sum }_{h = 1}^{n} \vert {y}_{c} ( i ) - y ( i ) \vert \\ s . t . h ∈ [ a , b ]\end{matrix} .$$

Another objective of the present invention is to provide a progressive power grid planning evaluation system based on a combination assessment theory, which can solve the problems of low efficiency and accuracy of an existing assessment method in processing mass complex power grid data by systematically collecting, processing and analyzing the power grid data in combination with an LSTM network and an attention mechanism to construct and train deep learning model.

To solve the above technical problem, the present invention provides the following technical solution: a progressive power grid planning evaluation system based on a combination assessment theory includes: a data processing module, a feature engineering module, a deep learning model training module, and a regularization and optimization module.

The data processing module is responsible for collecting historical data and real-time data from a power grid system.

The feature engineering module is responsible for selecting and constructing features required for assessment.

The deep learning model training module is responsible for constructing and training a model of a LSTM network combined with an attention mechanism.

the regularization and optimization module is responsible for preventing model from overfitting.

A computer device is provided, including a memory in which a computer program is stored and a processor, where when the computer program is executed by the processor, the steps of the above progressive power grid planning evaluation method based on the combination assessment theory are implemented.

A computer-readable storage medium is provided, storing a computer program therein, where when the computer program is executed by a processor, the steps of the above progressive power grid planning evaluation method based on the combination assessment theory are implemented.

The present invention has the beneficial effects that: the present invention ensures objectivity and fairness of the assessment result through the subjective and objective combination weighting method, making assessment more comprehensive. The present invention can process mass complex power grid data through a deep learning model, especially the LSTM network and the attention mechanism, so as to improve the efficiency and the accuracy of assessment. The systematic method of the present invention is not only applicable to assessment of a power grid, but also can be extended to assessment and analysis in other fields, thereby having a wide application prospect. By automatically optimizing design of an assessment parameter, the present invention can be adaptively adjusted according to the historical data and the real-time data, making the assessment result closer to reality and improving practicability of assessment.

### BRIEF DESCRIPTION OF DRAWINGS

To more clearly describe the technical solutions of the embodiments of the present invention, the accompanying drawings required to describe the embodiments are briefly described below. Apparently, the accompanying drawings described below are only some embodiments of the present invention. Those skilled in the art may further obtain Other drawings based on these accompanying drawings without inventive effort. In the drawings:

FIG. 1 is an overall flowchart of a progressive power grid planning evaluation method based on a combination assessment theory provided by a first embodiment of the present invention; and

FIG. 2 is an overall block diagram of a progressive power grid planning evaluation system based on a combination assessment theory provided by a second embodiment of the present invention.

### DETAILED DESCRIPTION OF THE EMBODIMENTS

In order to make the aforementioned purposes, features and advantages of the present invention more apparent and comprehensible, detailed descriptions of specific embodiments of the present invention are provided below in conjunction with the appended drawings. It is understood that the described embodiments are merely a part of the embodiments of the present invention, rather than all embodiments. Based on the embodiments of the present invention, all other embodiments obtained by those of ordinary skill in the art without creative efforts shall fall within the protection scope of the present invention.

While the following description provides numerous specific details to fully comprehend the present invention, alternative implementations not explicitly disclosed herein are also possible. Those skilled in the art can carry out similar promotions without deviating from the scope of the present invention, thus the present invention is not limited to the specific embodiments disclosed below.

Secondly, the term “one embodiment” or “embodiments” referred herein refers to specific features, structures, or characteristics that may be incorporated into at least one implementation of the present invention. The term ‘in one embodiment’ appearing in different places in the present specification does not necessarily refer to the same embodiment, nor is it a separate or selective embodiment that is mutually exclusive with other embodiments.

The present invention is described in detail in conjunction with schematic diagrams. For the purpose of description, sectional views of the device structure are partially enlarged without being drawn to scale. The schematic diagrams are merely exemplary and should not limit the protection scope of the present invention. Furthermore, it is important to consider the three-dimensional spatial dimensions of length, width, and depth in actual production.

It should be noted that in the description of the present invention that terms such as “up, down, inside, and outside” indicating orientation or positional relationships are based on the orientation or positional relationships shown in the illustrations for the purpose of facilitating the description and simplifying the disclosure. They do not indicate or imply that the device or the components referred to must have a specific orientation, be constructed in a specific orientation, or operate in a specific orientation, and therefore should not be construed as limiting the present invention. Moreover, terms like “first, second or third” are only used for description, and should not be considered as a designation or designation of relative importance.

Unless otherwise explicitly specified and limited in the present invention, the terms “installation, connection, linking” should be understood in a broad sense. For example, they could refer to fixed or detachable connections, as well as integrally formed connections. They could also encompass mechanical, electrical or direct connections, indirect connections via intermediaries, and connections within two components. The terms described above have specific meanings in the present invention that can be understood by those skilled in the art in light of the particular circumstances.

### Embodiment 1

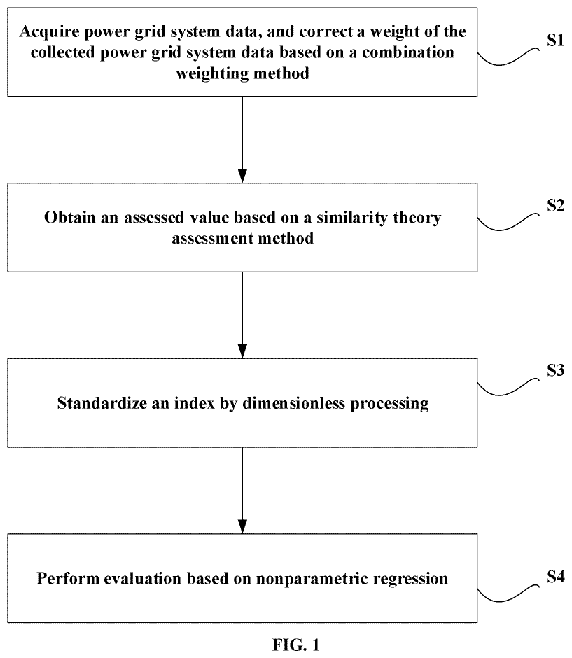

Referring to FIG. 1, which shows an embodiment of the present invention, a progressive power grid planning evaluation method based on a combination assessment theory is provided, including:

S1: acquiring power grid system data, and correcting a weight of the collected power grid system data based on a combination weighting method.

The power grid system data includes power grid operation state data, power grid equipment operation data, power grid load data, power grid fault data, and power grid environment data.

The combination weighting method includes a subjective weighting method and an objective weighting method, and the weighting method is selected according to the performance analysis of a power grid system.

A data index of the power grid system is assessed according to the subjective weighting method to generate a judgment matrix, normalization checking is preformed on the judgment matrix, and a system weight of the matrix is obtained by iterative calculation;

The data index of the power grid system is weighted by the objective weighting method to generate an original data matrix, and a comprehensive weight of the power grid system is obtained by dimensionless processing and normalization processing on a weight value.

The generating a judgment matrix includes: comparing evaluation factors, and filling a comparison result into the judgment matrix.
the normalization checking represents that

$$CI = \frac{{λ}_{max} - n}{n - 1}$$

$$CR = \frac{CI}{RI}$$

if CR is smaller than 0.1, normalization checking passes,
where CI represents a consistency index, λ_{mad} represents a maximum eigenvalue of the judgment matrix, CR represents a consistency ratio, RI represents a random consistency index, and n represents a number of the evaluation factors.

More further, the obtaining a comprehensive weight of the power grid system includes: calculating a weight of each data index according to the objective weighting method, and performing a check according to the Kendall's concordance coefficient test method.

If d(W⁽¹⁾, W⁽²⁾) is larger than a test threshold, it represents that a test passes; and if the test passes, the comprehensive weight of the power grid system is calculated by using

$$\text{?}$$

$$\text{?} \text{indicates text missing or illegible when filed}$$

the Kendall's concordance coefficient test method is expressed as:

$$d ( {W}^{( 1 )} , {W}^{( 2 )} ) = {[ \frac{1}{2} {\sum }_{j = 1}^{n} {( {w}_{j}^{( 1 )} - {w}_{j}^{2} )}^{2} ]}^{\frac{1}{2}}$$

where d(W⁽¹⁾, W⁽²⁾) represents an Euclidean distance between weight vectors W⁽¹⁾ and W⁽²⁾;

$${( {W}_{j}^{( 1 )} , {W}_{j}^{( 2 )} )}^{2}$$

represents a square of a difference between the weight values of the two weight vectors at the j^{th} position;

$${\sum }_{j = 1}^{n}$$

represents calculation on all weight differences; W represents the comprehensive weight of the power grid system; λₖ represents a weight of the k^{th} evaluation standard; and q represents a total number of evaluation standards.

S2: obtaining an assessed value based on a similarity theory assessment method.

Further, the similarity theory assessment method includes: constructing a new model for power grid system level evaluation by a Shepard similarity interpolation method based accelerated genetic algorithm and ideal interval method based on a genetic algorithm.

The constructing a new model for power grid system level evaluation includes: randomly generating power grid data evaluation level sample series x(i, j) and y(i) according to a system evaluation standard table, where i=1−n, and j=1−m; and
performing optimization estimation according to a sample parameter b, taking a sample i from the sample series, and obtaining an interpolation, denoted as y_{c}(i) corresponding to an evaluation level y(i) by Shepard interpolation with other n−1 samples.

The accelerated genetic algorithm is expressed as:

$$min f ( b ) = {\sum }_{i = 1}^{n} \vert {y}_{c} ( i ) - y ( i ) \vert$$

$$s . t . 1 \leq b \leq 5$$

where

$${\sum }_{i = 1}^{n}$$

represents a summation symbol, y_{c}(i) represents the i^{th} observed value, y(i) represents the i^{th} actual value, and s.t. represents a constraint condition.

The ideal interval method based on the genetic algorithm includes: generating the evaluation standard sample series, performing dimensionless processing, calculating a distance between each standard sample and a standard level ideal interval, and calculating a relative membership degree value and an equivalent comprehensive evaluation of each standard sample to the standard level ideal interval.

S3: standardizing an index by dimensionless processing.

Further, the dimensionless processing is expressed as:

$$x ( k , j ) = x * ( k , j ) / {x}_{max} ( j ) ( k = 1 \sim {n}_{k} , j = 1 \sim {n}_{j} )$$

$$a ( i , j ) = a * ( i , j ) / {x}_{max} ( j ) ( i = 1 \sim {n}_{i} , j = 1 \sim {n}_{j} )$$

$$b ( i , j ) = b * ( i , j ) / {x}_{max} ( j ) ( i = 1 \sim {n}_{i} , j = 1 \sim {n}_{j} )$$

where x(k, j), a(i, j), and b(i, j) represent two-dimensional variables, x*(k, j), a*(i, j), and b*(i, j) represent original values of x(k, j), a(i, j), and b(i, j) respectively, and xₘₐₓ(j) max represents a maximum value of the j^{th} evaluation index that may be taken from the evaluation standard sample series, expressed as:

$${x}_{max} ( j ) = {max}_{i} \{ b * ( i , j ) \}$$

the distance between each standard sample and the standard level ideal interval is expressed as:

$$D ( k , i ) = {\sum }_{j = 1}^{{n}_{j}} w ( j ) d ( k , i , j )$$

$$d \{ \begin{matrix}a ( i , j ) - x ( k , j ) , & x ( k , j ) < a ( i , j ) \\ 0 , & x ( k , j ) ∈ [ a ( i , j ) , b ( i , j ) ] \\ x ( k , j ) - b ( i , j ) , & x ( k , j ) > b ( i , j )\end{matrix}$$

where D(k, i) represents a total distance between the k^{th} observed value and the i^{th} reference value, w(j) represents a weight of the j^{th} index, d(k, i, j) represents a distance between the k^{th} observed value and the i^{th} reference value on the j^{th} feature, a(i, j) and b(i, j) represent a lower bound and an upper bound of the i^{th} reference value on the j^{th} feature, and x(k, j) represents a value of the k^{th} observed value on the j^{th} feature.

S4: performing evaluation based on nonparametric regression.

The performing evaluation based on nonparametric regression includes: obtaining a one-dimensional projection value z(i) of the assessed value, expressed as:

$$z ( i ) = {\sum }_{j = 1}^{p} a ( j ) x ( i , j )$$

obtaining a projection index function by means of the one-dimensional projection value, expressed as:

$$Q ( a ) = {S}_{z} \vert {R}_{xy} \vert$$

where [symbol] represents an absolute value, and S_{z} represents a standard deviation of a projection value z(i);
estimating an optimal projection direction by solving a maximization problem of the projection index function

$$max Q ( a ) = {S}_{z} \vert {R}_{xy} \vert$$

$$s . t . {\sum }_{j = 1}^{p} {a}^{2} ( j ) = 1 ;$$

and
performing optimization by using the accelerated genetic algorithm.

The performing evaluation based on nonparametric regression further includes: establishing a corresponding a Nadaraya-Watson nonparametric model, expressed as:

$${y}_{c} ( k ) = \frac{{\sum }_{i = 1}^{n} K ( ( z * ( i ) - z ( k ) ) / h ) y ( i )}{{\sum }_{i = 1}^{n} K ( ( z * ( i ) - z ( k ) ) / h )}$$

performing optimization estimation by using a standard evaluation object series {z*(i)|i=1˜n} and the accelerated genetic algorithm to solve the following optimization problems, expressed as:

$$\begin{matrix}min & f ( h ) = {\sum }_{h = 1}^{n} \vert {y}_{c} ( i ) - y ( i ) \vert \\ s . t . & h ∈ [ a , b ]\end{matrix} .$$

### Embodiment 2

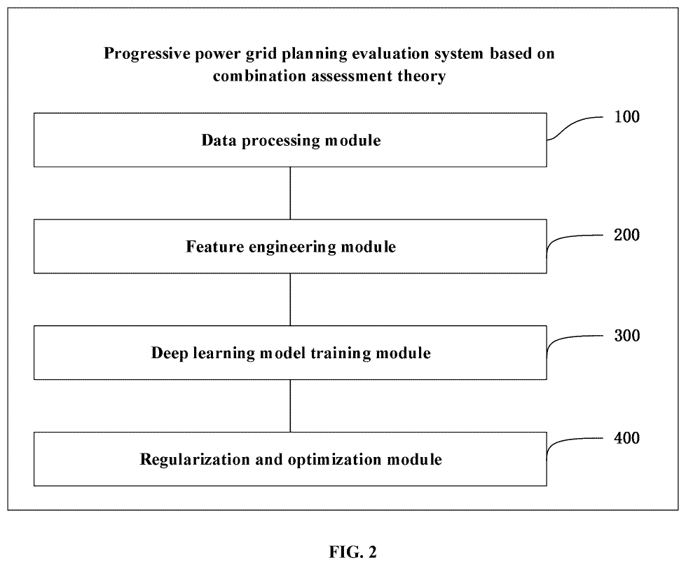

Referring to FIG. 2, which shows an embodiment of the present invention, a system for the progressive power grid planning evaluation method based on the combination assessment theory is provided. The progressive power grid planning evaluation system based on the combination assessment theory includes: a data processing module, a feature engineering module, a deep learning model training module, and a regularization and optimization module.

The data processing module is responsible for collecting historical data and real-time data from a power grid system; the feature engineering module is responsible for selecting and constructing features required for assessment; the deep learning model training module is responsible for constructing and training a model of a LSTM network combined with an attention mechanism; and the regularization and optimization module is responsible for preventing model from overfitting.

If a function is implemented in a form of a software functional unit, and sold or used as an independent product, the function may be stored in a computer-readable storage medium. Based on this understanding, the technical solution of the present invention essentially or a part that contributes to the prior art; or part of the technical solution may be embodied in a form of a software product; and the computer software product is stored in a storage medium and includes a plurality of instructions which are used to enable a computer device (which may be a personal computer, a server, or a network device, etc.) to execute all or part of the steps of the methods described in the various embodiments of the present invention. The foregoing storage medium includes various media that can store program codes, such as a USB flash drive, a mobile hard disk, a read-only memory (ROM), a random access memory (RAM), a magnetic disk, or an optical disc.

Logics and/or steps expressed in the flow chart or otherwise described herein, for example, may be considered as a sequence table of executable instructions for implementing logical functions, and may be implemented in any computer-readable medium for use by instruction execution systems, apparatuses, or devices (such as computer-based systems, systems including processors, or other systems that may acquire instructions from the instruction execution systems, the apparatuses, or the devices and execute the instructions), or in a combination manner. For the purposes of this specification, the “computer-readable medium” may be any device that may contain, store, communicate, propagate or transmit a program for use by the instruction execution systems, the apparatuses, or the devices or in a combination manner.

More specific examples of the machine-readable storage medium (non-exhaustive list) may include an electrical connection (an electronic apparatus) with one or more wires, a portable computer disk case (a magnetic apparatus), a random access memory (RAM), a read-only memory (ROM), an erasable programmable read-only memory (EPROM or flash memory), an optical fiber, and a portable compact disk read-only memory (CDROM). In addition, the computer-readable medium may even be paper or other appropriate media on which the program may be printed. It because that the program may be acquired electronically, for example, by optically scanning the paper or other media, followed by editing, interpretation or, if necessary, other appropriate processing ways, and then stored in a computer memory.

It should be understood that each part of the present invention can be achieved by hardware, software, firmware or a combination thereof. In the above implementation, multiple steps or methods can be implemented with the software or the firmware stored in the memory and executed by the appropriate instruction execution system. For example, if they are implemented by the hardware, as in another implementation, they may be implemented by any one of the following technologies well known in the art or their combination: a discrete logic circuit with a logic gate circuit for implementing a logic function of a data signal, a special integrated circuit with an appropriate combinational logic gate circuit, a programmable gate array (PGA), a field programmable gate array (FPGA), etc.

### Embodiment 3

In the embodiment, in order to verify the beneficial effects of the present invention, scientific demonstration is performed through economic benefit calculation and a simulation experiment.

Data source: the historical data and the real-time data of a power grid in a certain area are selected, including key indexes such as a current, a voltage, a power, a frequency, and a harmonic content.

Assessment objectives: stability, efficiency, reliability, a response speed, a fault-tolerant capability, and economy of the power grid.

Assessment method: on one hand, the method of the present invention is used; and on the other hand, the traditional power grid assessment method is used.

The embodiment experiments the existing traditional method and the method of the embodiment respectively, as shown in Table 1.

TABLE 1
Comparison diagram of experimental results

| | Score of traditional | Score of invention |
|---|---|---|
| Evaluation index | method | method |
| Stability | 75 | 92 |
| Efficiency | 80 | 95 |
| Reliability | 78 | 94 |
| Response speed | 70 | 90 |
| Fault-tolerant capability | 72 | 91 |
| Economy | 77 | 93 |

From the above table, it can be seen that all the assessment indexes using the assessment method of the present invention are higher than those using the traditional method. This shows that the method of the present invention is more accurate and comprehensive, and can better reflect actual performance of the power grid.

It should be noted that the above embodiments are only used to illustrate the technical solution of the present invention and are not for limitation. Although the present invention is described in detail with reference to the preferred embodiments, those of ordinary skill in the art should understand that the technical solutions of the present invention may be modified or replaced by equivalents without departing from the spirit and scope of the technical solutions of the present invention, and all those modifications or replacements should be included in the scope of the claims of the present invention.

What is claimed is:

1. A progressive power grid planning evaluation method based on a combination assessment theory, comprising:
acquiring power grid system data, and correcting a weight of the collected power grid system data based on a combination weighting method;
obtaining an assessed value based on a similarity theory assessment method;
standardizing an index by dimensionless processing; and
performing evaluation based on nonparametric regression.

2. The progressive power grid planning evaluation method based on the combination assessment theory according to claim 1, wherein the power grid system data comprises power grid operation state data, power grid equipment operation data, power grid load data, power grid fault data, and power grid environment data;
the combination weighting method comprises a subjective weighting method and an objective weighting method, and the weighting method is selected according to the performance analysis of a power grid system;
a data index of the power grid system is assessed according to the subjective weighting method to generate a judgment matrix, normalization checking is performed on the judgment matrix, and a system weight of the matrix is obtained by iterative calculation;
the data index of the power grid system is weighted by the objective weighting method to generate an original data matrix, and a comprehensive weight of the power grid system is obtained by dimensionless processing and normalization processing on a weight value; and
the generating a judgment matrix comprises comparing evaluation factors, and filling a comparison result into the judgment matrix, wherein
the normalization checking represents that
$$C I = \frac{{λ}_{max} - n}{n - 1}$$
$$C R = \frac{C I}{R I}$$
if CR is smaller than 0.1, normalization checking passes,
wherein CI represents a consistency index, λ_{mad} represents a maximum eigenvalue of the judgment matrix, CR represents a consistency ratio, RI represents a random consistency index, and n represents a number of the evaluation factors.

3. The progressive power grid planning evaluation method based on the combination assessment theory according to claim 2, wherein the obtaining a comprehensive weight of the power grid system comprises: calculating a weight of each data index according to the objective weighting method, and performing a check according to the Kendall's concordance coefficient test method, wherein
if d(W⁽¹⁾, W⁽²⁾) is larger than a test threshold, a test passes; and if the test passes, the comprehensive weight of the power grid system is calculated by using
$$W = {\sum }_{k = 1}^{q} {λ}_{k} {W}^{( k )} ;$$
and
the Kendall's concordance coefficient test method is expressed as:
$$d ( {W}^{( 1 )} , {W}^{( 2 )} ) = {[ \frac{1}{2} {\sum }_{j = 1}^{n} {( {w}_{j}^{( 1 )} - {w}_{j}^{( 2 )} )}^{2} ]}^{\frac{1}{2}}$$
wherein d(W⁽¹⁾, W⁽²⁾) represents an Euclidean distance between weight vectors W⁽¹⁾ and W⁽²⁾;
$${( {W}_{j}^{( 1 )} , {W}_{j}^{( 2 )} )}^{2}$$
represents a square of a difference between the weight values of the two weight vectors at the j^{th} position;
$${\sum }_{j = 1}^{n}$$
represents calculation on all weight differences; W represents the comprehensive weight of the power grid system; λₖ represents a weight of the k^{th} evaluation standard; and q represents a total number of evaluation standards.

4. The progressive power grid planning evaluation method based on the combination assessment theory according to claim 3, wherein the similarity theory assessment method comprises: constructing a new model for power grid system level evaluation by a Shepard similarity interpolation method based on an accelerated genetic algorithm and an ideal interval method based on a genetic algorithm, wherein
the constructing a new model for power grid system level evaluation comprises: randomly generating power grid data evaluation level sample series x(i, j) and y(i) according to a system evaluation standard table, wherein i=1−n, and j=1−nⱼ; and
performing optimization estimation according to a sample parameter b, taking a sample i from the sample series, and obtaining an interpolation, denoted as y_{c}(i), corresponding to an evaluation level y(i) by Shepard interpolation with other n−1 samples;
the accelerated genetic algorithm is expressed as:
$$min f ( b ) = {\sum }_{i = 1}^{n} \vert {y}_{c} ( i ) - y ( i ) \vert$$
$$s . t . 1 \leq b \leq 5$$
wherein
$${\sum }_{i = 1}^{n}$$
represents a summation symbol, y_{c}(i) represents the i^{th} observed value, y(i) represents the i^{th} actual value, and s.t. represents a constraint condition; and
the ideal interval method based on the genetic algorithm comprises: generating the evaluation standard sample series, performing dimensionless processing, calculating a distance between each standard sample and a standard level ideal interval, and calculating a relative membership degree value and an assessed value of each standard sample to the standard level ideal interval.

5. The progressive power grid planning evaluation method based on the combination assessment theory according to claim 4, wherein the dimensionless processing is expressed as:
$$x ( k , j ) = x * ( k , j ) / {x}_{m ax} ( j ) ( k = 1 \sim {n}_{k} , j = 1 \sim {n}_{j} )$$
$$a ( i , j ) = a * ( i , j ) / {x}_{m ax} ( j ) ( i = 1 \sim {n}_{i} , j = 1 \sim {n}_{j} )$$
$$b ( i , j ) = b * ( i , j ) / {x}_{m ax} ( j ) ( i = 1 \sim {n}_{i} , j = 1 \sim {n}_{j} )$$
wherein x(k, j), a(i, j), and b(i, j) represent two-dimensional variables x*(k, j), a*(i, j), and b*(i, j) represent original values of x(k, j) a(i, j), and b(i, j) respectively, and xₘₐₓ(j) represents a maximum value of the j^{th} evaluation index that may be taken from the evaluation standard sample series, expressed as:
$${x}_{ma x} ( j ) = {max}_{i} \{ b * ( i , j ) \}$$
the distance between each standard sample and the standard level ideal interval is expressed as:
$$D ( k , i ) = {\sum }_{j = 1}^{{n}_{j}} w ( j ) d ( k , i , j )$$
$$d \{ \begin{matrix}a ( i , j ) - x ( k , j ) , & x ( k , j ) < a ( i , j ) \\ 0 , & x ( k , j ) ∈ [ a ( i , j ) , b ( i , j ) ] \\ x ( k , j ) - b ( i , j ) , & x ( k , j ) > b ( i , j )\end{matrix}$$
wherein D(k, i) represents a total distance between the k^{th} observed value and the i^{th} reference value, w(j) represents a weight of the j^{th} index, d(k, i, j) represents a distance between the k^{th} observed value and the i^{th} reference value on the j^{th} feature, a(i, j) and b(i, j) represent a lower bound and an upper bound of the i^{th} reference value on the j^{th} feature, and x(k, j) represents a value of the k^{th} observed value on the j^{th} feature, wherein k=1−nₖ;
the relative membership degree value is expressed as:
$$min f ( c ) = {\sum }_{k = 1}^{{n}_{k}} \vert h ( k ) - y ( k ) \vert$$
wherein h(k) represents a quality level value of the observed value k, and y(k) represents a true value of the observed value k; and
the assessed value is expressed as: {z*(k, j)|k=1˜n_{z}, j=1˜nⱼ}.

6. The progressive power grid planning evaluation method based on the combination assessment theory according to claim 5, wherein the performing evaluation based on nonparametric regression comprises: obtaining a one-dimensional projection value z(i) of the assessed value, expressed as:
$$z ( i ) = {\sum }_{j = 1}^{p} a ( j ) x ( i , j )$$
obtaining a projection index function by means of the one-dimensional projection value, expressed as:
$$Q ( a ) = {S}_{z} \vert {R}_{x y} \vert$$
wherein [symbol] represents an absolute value, and S_{z} represents a standard deviation of a projection value z(i);
estimating an optimal projection direction by solving a maximization problem of the projection index function
$$max Q ( a ) = {S}_{z} \vert {R}_{x y} \vert$$
$$s . t . {\sum }_{j = 1}^{p} {a}^{2} ( j ) = 1 ;$$
and
performing optimization by using the accelerated genetic algorithm.

7. The progressive power grid planning evaluation method based on the combination assessment theory according to claim 6, wherein the performing evaluation based on nonparametric regression further comprises: establishing a corresponding a Nadaraya-Watson nonparametric model, expressed as:
$${y}_{c} ( k ) = \frac{{\sum }_{i = 1}^{n} K ( ( z * ( i ) - z ( k ) ) / h ) y ( i )}{{\sum }_{i = 1}^{n} K ( ( z * ( i ) - z ( k ) ) / h )}$$
performing optimization estimation by using a standard evaluation object series {z*(i)|i=1˜n} and the accelerated genetic algorithm to solve the following optimization problems, expressed as:
$$min f ( h ) = {\sum }_{h = 1}^{n} \vert {y}_{c} ( i ) - y ( i ) \vert$$
$$s . t . h ∈ [ a , b ]$$

8. A system using the progressive power grid planning evaluation method based on the combination assessment theory according to claim 1, comprising: a data processing module, a feature engineering module, a deep learning model training module, and a regularization and optimization module, wherein
the data processing module is responsible for collecting historical data and real-time data from a power grid system;
the feature engineering module is responsible for selecting and constructing features required for assessment;
the deep learning model training module is responsible for constructing and training a model of a LSTM network combined with an attention mechanism; and
the regularization and optimization module is responsible for preventing model from overfitting.

9. A computer device, comprising a memory in which a computer program is stored and a processor, wherein when the computer program is executed by the processor, the steps of the progressive power grid planning evaluation method based on the combination assessment theory according to claim 1 are implemented.

10. A computer-readable storage medium in which a computer program is stored, wherein when the computer program is executed by a processor, the steps of the progressive power grid planning evaluation method based on the combination assessment theory of claim 1 are implemented.
